(19) United States
(12) Patent Application Publication
(10) Pub. No.: US 2006/0270118 A1
(43) Pub. Date: Nov. 30, 2006

(54) Surface mount type semiconductor device and method of manufacturing the same

(76) Inventors: Hiroyuki Okura, Yokohama-shi (JP); Tetsuya Sato, Yokkaichi-shi (JP); Takashi Imoto, Yokkaichi-shi (JP); Katsuhiko Oyama, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/442,996

(22) Filed: May 31, 2006

(30) Foreign Application Priority Data
May 31, 2005 (JP) 2005-160683

(51) Int. Cl. H01L 21/00; H01L 23/48

(52) U.S. Cl. 438/127; 257/782; 257/783; 257/737

(57) ABSTRACT

A surface mount type semiconductor device comprises a support substrate having mutually opposed first and second surfaces, and having a slit at a central part thereof, a semiconductor element including electrode pads at least a central part thereof, the semiconductor element being mounted on the first surface such that the electrode pads are located within the slit, a width of the semiconductor element is less than a longitudinal length of the slit and both ends of the slit are located outside end portions of the semiconductor element, metal fine wires for electrically connecting the electrode pads to the connection terminals on the second surface, a first seal resin member provided to seal the semiconductor element on the first surface, and a second seal resin member provided to seal the slit on the second surface.

### CROSS-REFERENCE TO RELATED APPLICATIONS

This application is based upon and claims the benefit of priority from the prior Japanese Patent Application No. 2005-160683, filed May 31, 2005, the entire contents of which are incorporated herein by reference.

### BACKGROUND OF THE INVENTION

1. Field of the Invention

The present invention relates generally to a surface mount type semiconductor device and a method of manufacturing the same, and more particularly to a surface mount type semiconductor device with a face down structure and a method of manufacturing the same.

2. Description of the Related Art

In a surface mount type semiconductor device using a conventional substrate component, connection terminals, ball lands and wiring circuits for connecting them are formed of a thin film of a metallic material, such as copper, on a surface of a thin plate which is formed of a glass epoxy material or a polyimide material. A solder resist is coated on the surface of the thin plate in order to protect the wiring circuits, thus forming the substrate component (see, e.g. Jpn. Pat. Appln. KOKAI Publication No. 2001-85565).

A slit is provided in a central part of the substrate component, and a semiconductor element having a center pad structure or a peripheral pad structure is attached via an adhesive by a face down method. Then, electrode pads, which are formed on a surface of the semiconductor element, are electrically connected to the connection terminals, which are connected to the wiring circuits, by means of fine wires of, e.g. gold.

Subsequently, the surface side of the semiconductor element and the ball side of the substrate component are sealed with a seal resin material by transfer molding. Solder balls are bonded to the ball lands that are formed on the ball side of the substrate component, and the resultant structure is cut to a desired size, thereby providing a package.

When the sealing using the seal resin material is performed by the transfer molding, seal resin injection ports are provided on both the surface side of the semiconductor element and the ball side of the substrate component, or the ball surface side is sealed in a separate step by a method such as potting or printing.

However, there are restrictions on the positions of the injection ports in the case of the sealing on the ball surface side by the injection method. This poses a problem with the mold design. Moreover, in the case of the sealing of the center pad structure which has electrode pads at the central area of the semiconductor element and in the case of the sealing of the semiconductor element having electrode pads at the peripheral part of the semiconductor element, sealing is performed even on parts that require no sealing. In other words, it is difficult to seal only the electrode pad section on the peripheral part of the semiconductor element. As a result, not only the degree of freedom on the package design is decreased, but also a serious problem arises in connection with the warpage of the package and the filling of the seal resin. Besides, in the case of using a method such as potting, the number of fabrication step increases, the time for fabrication increases and an excess cost of material is incurred. This leads to an increase in manufacturing cost.

In any case, in the conventional surface mount type semiconductor device, it is difficult to seal only the electrode pad section on the peripheral part of the semiconductor element. There are restrictions on the positions of the injection ports for seal resin material, and there is the problem with the mold design. Moreover, the degree of freedom on the package design is decreased, and the problem arises in connection with the filling of the seal resin.

### BRIEF SUMMARY OF THE INVENTION

According to a first aspect of the present invention, there is provided a surface mount type semiconductor device which comprises: a support substrate having mutually opposed first and second surfaces, having a slit at a central part thereof, and having, on the second surface, ball lands, connection terminals and wiring circuits for connecting the ball lands and the connection terminals, a semiconductor element including electrode pads at least a central part thereof, the semiconductor element being mounted on the first surface such that the electrode pads are located within the slit, a width of the semiconductor element is less than a longitudinal length of the slit and both ends of the slit are located outside end portions of the semiconductor element, metal fine wires for electrically connecting the electrode pads to the connection terminals on the second surface, a first seal resin member provided to seal the semiconductor element on the first surface, and a second seal resin member provided to seal the slit on the second surface.

According to a second aspect of the present invention, there is provided a method of manufacturing a surface mount type semiconductor device, which comprises: preparing a substrate having mutually opposed first and second surfaces, forming a slit at a central part of the substrate, the slit having such a length as to exceed end portions of a semiconductor element which is to be resin-sealed on the first surface, forming a plurality of connection terminals, ball lands and wiring circuits for connecting the connection terminals and the ball lands by a thin film of a metallic material on the second surface of the substrate, attaching the semiconductor element, which has a center pad structure, to the first surface by a face down method such that the plurality of electrode pads are exposed to the second surface through the slit, electrically connecting the exposed electrode pads and the connection terminals, which are connected to the wiring circuits, by fine wires, forming first and second seal resin members, the first seal resin member being provided to seal the semiconductor element on the first surface, the second seal resin member being provided to seal the slit on the second surface, by placing the substrate with the semiconductor element in a mold, injecting a seal resin from a seal resin injection port which is formed on the first surface, and sealing the exposed electrode pads, the connection terminals and the fine wires, which are associated with the slit, with a seal resin member, bonding solder balls to the ball lands; and cutting a resultant structure to a desired size to provide a package.

### BRIEF DESCRIPTION OF THE DRAWINGS

FIG. 1 is a top view that schematically shows a substrate component of a surface mount type semiconductor device according to a first embodiment;

FIG. 2 is a bottom view that schematically shows the substrate component of the surface mount type semiconductor device according to the first embodiment;

FIG. 3 is a top view that schematically shows a state in which a semiconductor element having a center pad structure according to the first embodiment is attached to the upper surface of the substrate component by a face down method;

FIG. 4 is a bottom view that schematically shows a state in which the semiconductor element having the center pad structure according to the first embodiment is attached to the upper surface of the substrate component by the face down method;

FIG. 5 is a perspective view that schematically shows a state in which the semiconductor element side is being sealed with a seal resin member in the first embodiment;

FIG. 6 is a perspective view that schematically shows a state in which the semiconductor element side has been sealed with a seal resin member in the first embodiment;

FIG. 7 is a perspective view that schematically shows a state in which the lower surface side is being sealed with a seal resin member in the first embodiment;

FIG. 8 is a perspective view that schematically shows a state in which the lower surface side is being sealed with a seal resin member in the first embodiment;

FIG. 9 is a perspective view that schematically shows a state in which the lower surface side has been sealed with a seal resin member in the first embodiment;

FIG. 10 is a perspective view that schematically shows a state in which the semiconductor element side and the lower surface side have been sealed with seal resin members in the first embodiment;

FIG. 11 is a cross-sectional view that schematically shows the surface mount type semiconductor device according to the first embodiment;

FIG. 12 is a plan view that shows a lower surface side of the substrate component in a surface mount type semiconductor device according to a second embodiment;

FIG. 13 is a bottom view that schematically shows a state in which the lower surface side has been sealed with seal resin members in the second embodiment;

FIG. 14 is a bottom view that schematically shows a state in which the lower surface side has been sealed with seal resin members in the second embodiment;

FIG. 15 is a bottom view that schematically shows a state in which the lower surface side has been sealed with seal resin members in a modification of the second embodiment; and

FIG. 16 is a bottom view that schematically shows a state in which the lower surface side has been sealed with seal resin members in a modification of the second embodiment.

### DETAILED DESCRIPTION OF THE EMBODIMENTS

### First Embodiment

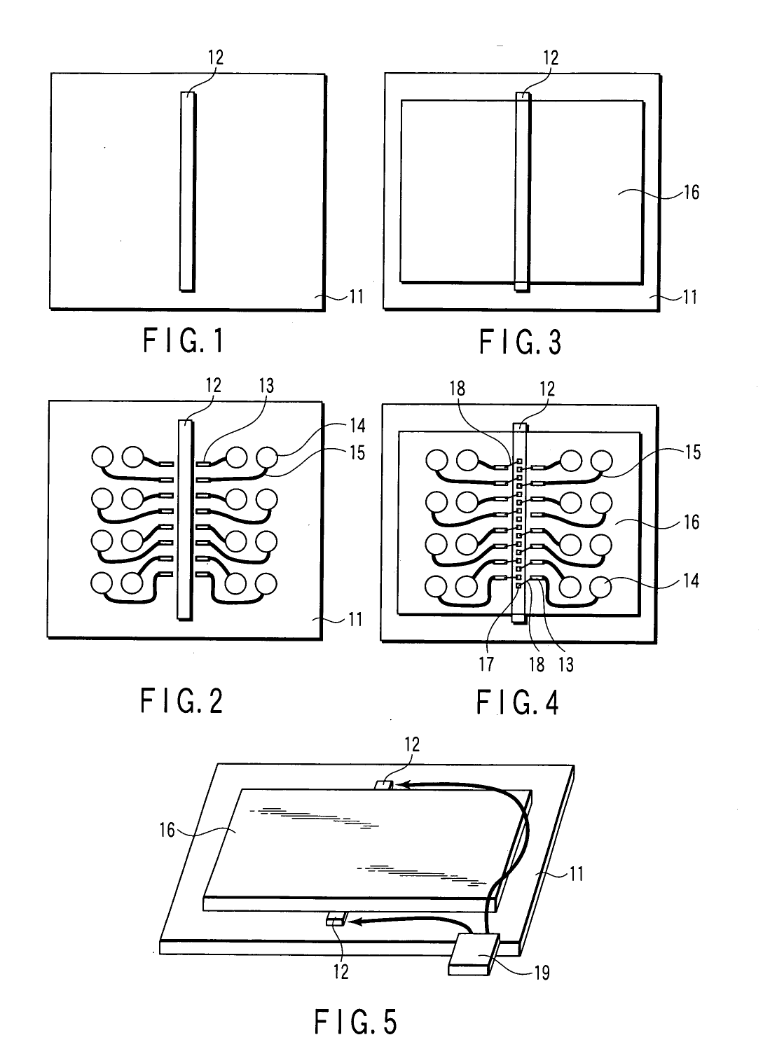

FIG. 1 to FIG. 11 show the structures of components of a surface mount type semiconductor device 10 according to a first embodiment. FIGS. 1 and 2 are a top view and a bottom view of a substrate component 11 on which a semiconductor element is to be mounted. Like the prior art, the substrate component 11 is formed of a glass epoxy material or a polyimide material. An elongated slit 12 is provided at a central part of the substrate component 11. The slit 12 has an elongated shape with such a length as to exceed end portions of the semiconductor element that is to be resin-sealed on a first surface, that is, an upper surface of the substrate component 11 so that a seal resin material may flow to the lower surface of the substrate component 11.

As shown in FIG. 2, a plurality of connection terminals 13, ball lands 14 and wiring circuits 15 for connecting these components are formed of a thin film of a metallic material, such as copper, on a second surface, that is, a lower surface of the substrate component 11. A solder resist for protecting the wiring circuits is coated on the thin plate surface.

As shown in FIGS. 3 and 4, a semiconductor element 16 having a center pad structure is attached to the upper surface of the substrate component 11 via an adhesive by a face down method. Electrode pads 17, which are exposed from the slit 12 on the lower surface of the substrate component 11, are electrically connected to the connection terminals 13, which are connected to the wiring circuits 15, by means of fine wires 18 of, e.g. gold. As is clear from FIGS. 2 and 4, the connection terminals 13 are arranged on both sides of the slit 12 with respect to the electrode pads 17 that are exposed from the slit 12. The slit 12 has such a length as to exceed end portions of the semiconductor element 16.

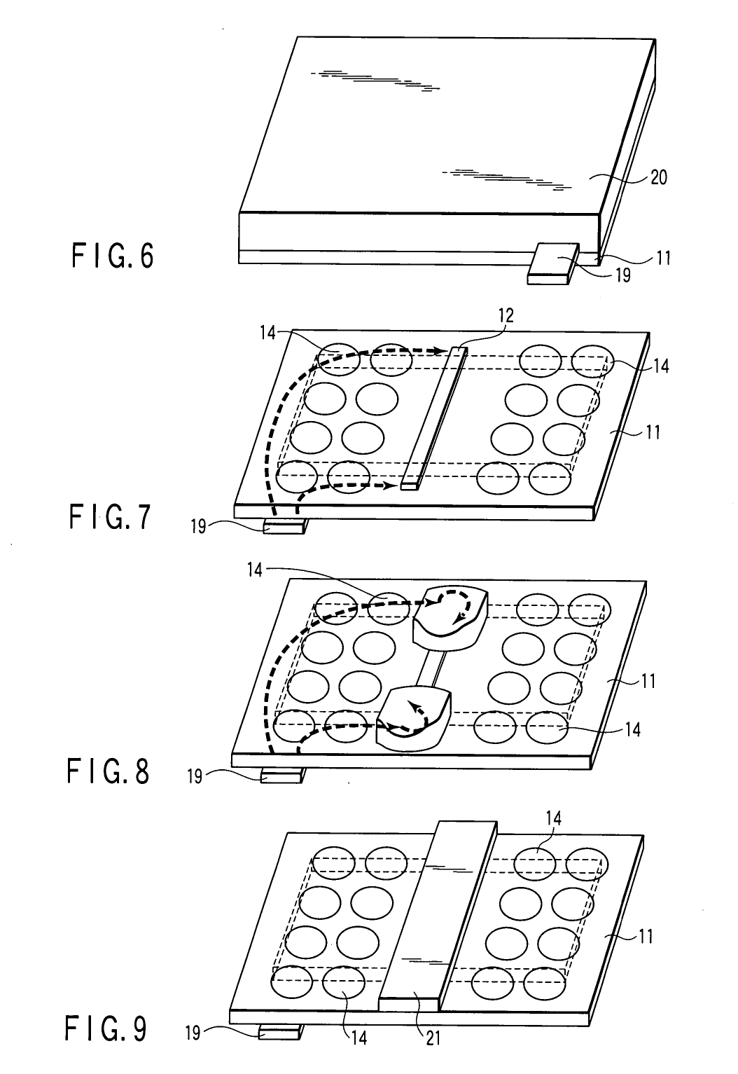

Subsequently, as shown in FIG. 5, the substrate component 11 with the semiconductor element 16 is put in a mold, and a seal resin is injected from a seal resin injection port 19. At this time, the seal resin flows as indicated by arrows, and the semiconductor element 16 on the upper surface of the substrate component 11 is sealed with a seal resin member 20, as shown in FIG. 6.

As regards the sealing on the ball surface side, that is, on the lower surface side of the substrate component 11, as shown in FIG. 7, the seal resin, which is injected from the semiconductor element surface side, flows to the slit 12 and passes through gaps between the semiconductor element 16 and the slit 12, thus advancing to the lower surface side of the substrate component 11. The resin that has come to the lower surface side moves, as indicated by arrows in FIG. 8, in accordance with the shape of the mold on the lower surface side, and the molding on the lower surface side is completed, as shown in FIG. 9. Thus, the lower surface side, that is, the exposed electrode pads 17, connection terminals 13 and fine wires 18, which are associated with the slit 12, are sealed with a seal resin member 21.

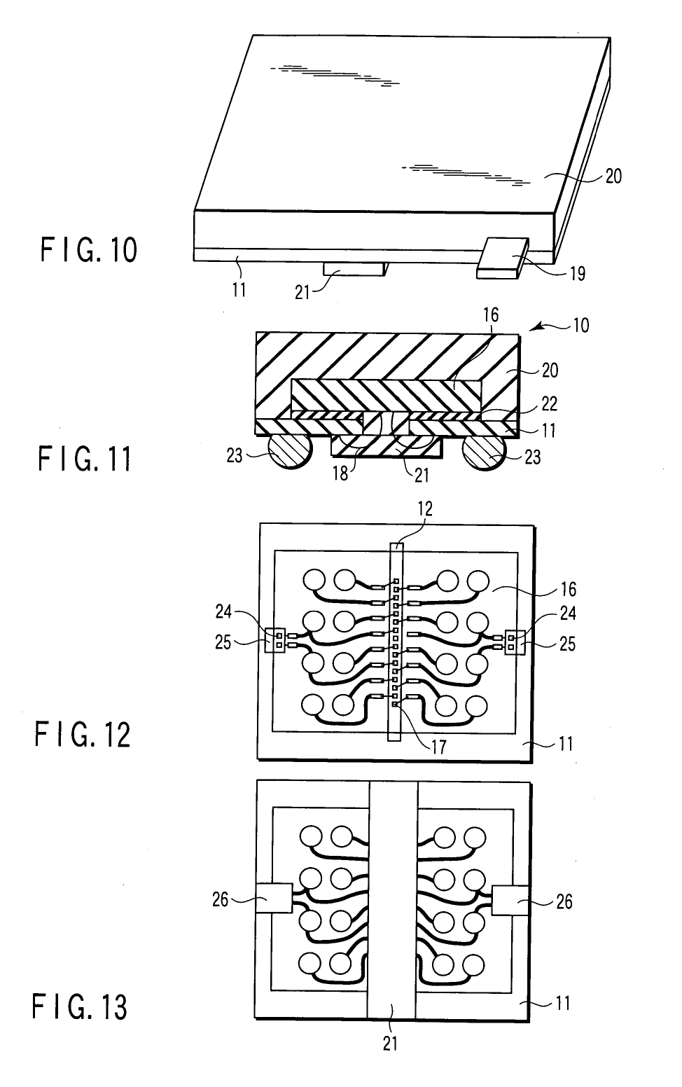

At last, as shown in FIG. 10, the semiconductor element surface side and the lower surface side can be sealed with the seal resin members 20 and 21 at a time. In this case, the sealing can sufficiently be performed if a gap of about 0.2 mm is provided between the slit 12 and the semiconductor element.

FIG. 11 shows a cross-sectional structure of the surface mount type semiconductor device 10. The semiconductor element 16 having the center pad structure is attached via an adhesive 22 by a face down method. Solder balls 23 are bonded to the ball lands that are formed on the ball side of the substrate component 11, and the resultant structure is cut to a desired size, thereby providing a package of the semiconductor device.

### Second Embodiment

FIGS. 12 to 14 show the lower surface side of the substrate component 11 of a surface mount type semiconductor device 10 according to a second embodiment of the invention. The second embodiment is basically the same as the first embodiment. A description of common parts is omitted, and only characteristic parts will be described.

In the first embodiment, the semiconductor element 16 having the center pad structure is provided on the upper surface of the substrate component 11 by the face down method. In the second embodiment, as shown in FIG. 12, the semiconductor element 16 has both a center pad structure and a peripheral pad structure including a plurality of electrode pads 24 at the peripheral part of the semiconductor element 16.

The electrode pads 24, which are formed on the peripheral part of the semiconductor element 16, are exposed from the peripheral part of the substrate component 11. Specifically, the electrode pads 24 are exposed from square openings 25 each having such a length as to exceed the end portion of the semiconductor element 16.

As is shown in FIG. 13, as regards the electrode pads 24, like the center pad structure, each square opening 25 is sealed with a seal resin so as to contain the electrode pads, metal fine wires and connection terminals. Thus, resin seal members 26 are formed on associated peripheral parts on the lower surface side so as to come in contact with the associated end portions of the package.

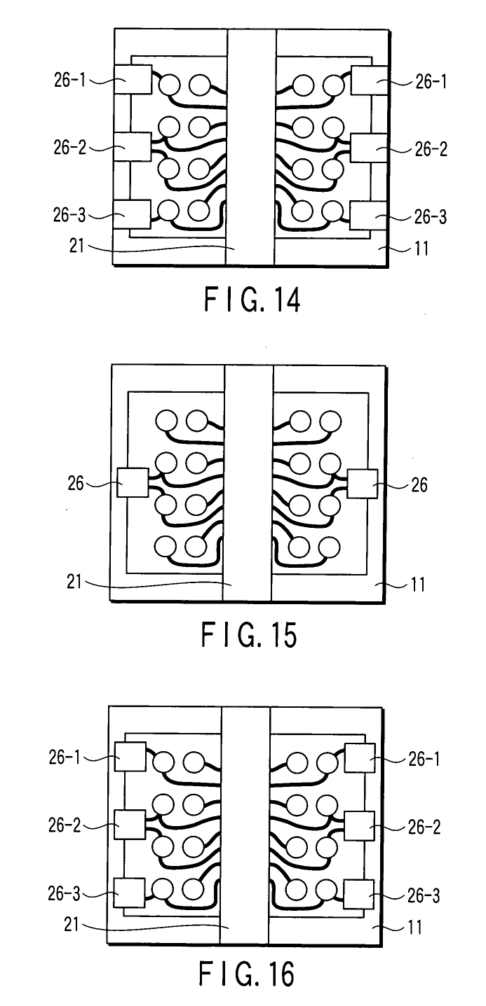

In FIG. 14, three seal resin members 26-1 to 26-3 and other three seal resin members 26-1 to 26-3 are formed on both sides of the seal resin member 21 on associated peripheral parts of the lower surface side so as to come in contact with associated end portions of the package. Subsequently, like the first embodiment, solder balls are bonded to the ball lands that are formed on the lower surface side of the substrate component 11. The resultant structure is cut to a desired size to provide the package.

FIGS. 15 and 16 show modifications of the second embodiment. In FIG. 13 and 14, the seal resin members 26 and 26-1 to 26-3 on the peripheral parts of the lower surface side are so formed as to contact the end portions of the package. In the modifications, the seal resin members are so formed as not to contact the end portions of the package, and the area of each seal resin member is reduced.

I. The fabrication steps of the surface mount type semiconductor device, in which the semiconductor element having the center pad structure is mounted, are as follows.

(1) There is prepared a substrate having mutually opposed first and second surfaces, the substrate being formed of a glass epoxy material or a polyimide material.

(2) An elongated slit is provided at a central part of the substrate. The slit has an elongated shape with such a length as to exceed end portions of the semiconductor element that is to be resin-sealed on the first surface.

(3) A plurality of connection terminals, ball lands and wiring circuits for connecting these components are formed of a thin film of a metallic material, such as copper, on the second surface of the substrate, and the substrate surface is coated with a solder resist for protecting the wiring circuits.

(4) The semiconductor element having a center pad structure is attached to the first surface by a face down bonding such that a plurality of electrode pads are exposed from the slit.

(5) The exposed electrode pads are electrically connected to the connection terminals, which are connected to the wiring circuits, by means of fine wires.

(6) The substrate with the semiconductor element is put in a mold, and a seal resin is injected from a seal resin injection port which is formed on the first surface of the substrate. Thereby, the semiconductor element on the first surface is sealed with a seal resin member. In addition, the seal resin flows to the slit and passes through gaps between the semiconductor element and the slit, thus advancing to the second surface side of the substrate. Thereby, the exposed electrode pads, connection terminals and fine wires, which are associated with the slit, are sealed with a seal resin member.

(7) Solder balls are bonded to the ball lands, and the resultant structure is cut to a desired size to provide a package.

According to this manufacturing method, the elongated slit with such a length as to exceed end portions of the semiconductor element is provided at the central part of the substrate. Thus, the seal resin members, which are to be formed on the first and second surfaces, need not be formed separately, but can be formed at a time.

II. Like the fabrication steps of the surface mount type semiconductor device in which the semiconductor element having the center pad structure is mounted, it is possible to manufacture, by the following fabrication steps, the surface mount type semiconductor device in which the semiconductor element having both the center pad structure and the peripheral pad structure including the electrode pads on the peripheral part of the semiconductor element is mounted.

(8) Square openings each having such a length as to exceed the end portion of the semiconductor element are formed symmetric with respect to the elongated opening that is formed at the central part of the substrate.

(9) The exposed electrode pads are electrically connected to the connection terminals, which are connected to the wiring circuits, by means of fine wires.

(10) The substrate with the semiconductor element is put in a mold, and a seal resin is injected from a seal resin injection port which is formed on the first surface of the substrate. Thereby, the semiconductor element on the first surface is sealed with a seal resin member. In addition, the seal resin flows to the slits and passes through gaps between the semiconductor element and the openings, thus advancing to the second surface side of the substrate. Thus, the exposed electrode pads, connection terminals and fine wires, which are associated with the openings, are sealed with seal resin members.

According to the above-described manufacturing methods, the seal resin members, which are to be formed on the first and second surfaces, need not be formed separately, but can be formed at a time. Moreover, the square openings, from which the peripheral electrode pads are exposed, can individually be sealed with the seal resin members.

As is clear from the above description, according to the present invention, the above-described drawbacks of the prior art can be overcome, and only the electrode pad sections on the peripheral parts of the semiconductor element can be sealed. The degree of freedom of the semiconductor element design can be increased, and the surface mount type semiconductor device with enhanced device characteristics and the manufacturing method therefor can be obtained.

The seal resin can be injected by the transfer molding at a time into only necessary parts, without contact with the ball lands. The number of fabrication steps, the time for manufacture and the cost for manufacture can be reduced. Moreover, since the positions of the electrode pads are not restricted, the degree of freedom of semiconductor element design is increased and the device characteristics are enhanced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A surface mount type semiconductor device comprising:
a support substrate having mutually opposed first and second surfaces, having a slit at a central part thereof, and having, on the second surface, ball lands, connection terminals and wiring circuits for connecting the ball lands and the connection terminals;
a semiconductor element including electrode pads at least a central part thereof, the semiconductor element being mounted on the first surface such that the electrode pads are located within the slit, a width of the semiconductor element is less than a longitudinal length of the slit and both ends of the slit are located outside end portions of the semiconductor element;
metal fine wires for electrically connecting the electrode pads to the connection terminals on the second surface;
a first seal resin member provided to seal the semiconductor element on the first surface; and
a second seal resin member provided to seal the slit on the second surface.

2. The surface mount type semiconductor device according to claim 1, wherein the slit is sealed with a seal resin such that the electrode pads, fine wires and the connection terminals are contained.

3. The surface mount type semiconductor device according to claim 1, wherein the semiconductor element has a center pad structure.

4. The surface mount type semiconductor device according to claim 1, wherein solder balls are bonded to the ball lands.

5. The surface mount type semiconductor device according to claim 1, wherein the slit has such as length as to exceed end portions of the semiconductor element.

6. The surface mount type semiconductor device according to claim 1, wherein the support substrate has at least one second slit at a peripheral part thereof, the semiconductor element includes electrode pads provided on the peripheral part thereof, and the surface mount type semiconductor device includes at least one third seal resin member provided to seal the second slit on the second surface.

7. The surface mount type semiconductor device according to claim 6, wherein the semiconductor element has the center pad structure and a peripheral pad structure.

8. The surface mount type semiconductor device according to claim 6, wherein solder balls are bonded to the ball lands.

9. The surface mount type semiconductor device according to claim 6, wherein the second slit is sealed with a seal resin such that the electrode pads, the metal fine wires and the connection terminals are contained.

10. The surface mount type semiconductor device according to claim 6, wherein said at least one third seal resin member is longer or shorter than an end portion of the semiconductor element.

11. The surface mount type semiconductor device according to claim 6, wherein said at least one third seal resin member is sealed such that the third seal resin member is in contact with a package end portion.

12. The surface mount type semiconductor device according to claim 6, wherein said at least one third seal resin member is sealed such that the third seal resin member is not in contact with the package end portion.

13. A method of manufacturing a surface mount type semiconductor device, the method comprising:
preparing a substrate having mutually opposed first and second surfaces;
forming a slit at a central part of the substrate, the slit having such a length as to exceed end portions of a semiconductor element which is to be resin-sealed on the first surface;
forming a plurality of connection terminals, ball lands and wiring circuits for connecting the connection terminals and the ball lands by a thin film of a metallic material on the second surface of the substrate;
attaching the semiconductor element, which has a center pad structure, to the first surface by a face down method such that the plurality of electrode pads are exposed to the second surface through the slit;
electrically connecting the exposed electrode pads and the connection terminals, which are connected to the wiring circuits, by fine wires;
forming first and second seal resin members, the first seal resin member being provided to seal the semiconductor element on the first surface, the second seal resin member being provided to seal the slit on the second surface, by placing the substrate with the semiconductor element in a mold, injecting a seal resin from a seal resin injection port which is formed on the first surface, and sealing the exposed electrode pads, the connection terminals and the fine wires, which are associated with the slit, with a seal resin member;
bonding solder balls to the ball lands; and
cutting a resultant structure to a desired size to provide a package.

14. The method of manufacturing a surface mount type semiconductor device, according to claim 13, wherein the seal resin flows to the slit and passes through gaps between the semiconductor element and the slit, thus advancing to the second surface side of the substrate and sealing the exposed electrode pads, the connection terminals and the fine wires with a seal resin member.

15. The method of manufacturing a surface mount type semiconductor device, according to claim 13, wherein the semiconductor element has a center pad structure.

16. The method of manufacturing a surface mount type semiconductor device, according to claim 13, further comprising:
forming square openings each having such a length as to exceed an end portion of the semiconductor element, the square openings being symmetric with respect to the slit that is formed in an elongated shape at the central part of the substrate;
electrically connecting the exposed electrode pads and the connection terminals, which are connected to the wiring circuits, by fine wires; and
resin-sealing the respective openings to form at least one third resin seal member on a peripheral part of the substrate.

17. The method of manufacturing a surface mount type semiconductor device, according to claim 16, wherein the semiconductor element has the center pad structure and a peripheral pad structure.

18. The method of manufacturing a surface mount type semiconductor device, according to claim 13, wherein a solder resist for protecting the wiring circuits is coated on the surface of the substrate.

19. The method of manufacturing a surface mount type semiconductor device, according to claim 16, wherein said at least one third seal resin member is sealed such that the third seal resin member is in contact with a package end portion.

20. The method of manufacturing a surface mount type semiconductor device, according to claim 16, wherein said at least one third seal resin member is sealed such that the third seal resin member is not in contact with a package end portion.
